(19) United States
(12) Patent Application Publication
(10) Pub. No.: US 2003/0160316 A1
(43) Pub. Date: Aug. 28, 2003

(54) Open-type multichips stack packaging

(76) Inventors: Wen-Lo Shieh, Taipei (TW); Fu-Yu Huang, Taipei (TW); Ning Huang, Taipei (TW); Hui-Pin Chen, Taipei (TW); Shu-Wan Lu, Taipei (TW); Tou-Sung Wu, Taipei (TW); Chih-Yu Tsai, Taipei (TW); Mei-Hua Chen, Taipei (TW); Chia-Ling Lu, Taipei (TW); Yu-Ju Wang, Taipei (TW)

Correspondence Address: Wen-Lo Shieh, PO Box 82-144, Taipei, TW

(21) Appl. No.: 10/340,739

(22) Filed: Jan. 13, 2003

(30) Foreign Application Priority Data
Feb. 26, 2002 (TW) 091103723

(51) Int. Cl. H01L 23/02

(52) U.S. Cl. 257/686

(57) ABSTRACT

An open-typed multi-chip stack-packaging is disclosed and the packaging comprises a substrate having a first surface and a second surface, at least a through opening formed on the substrate, and including at least two layers of circuitry to electrically transmit signals; at least a first chip positioned on the upper section of the opening of the first surface and a plurality of protruded blocks being soldered onto the circuitry on the first surface of the substrate at the external region of the substrate for electrically connection; at least a second chip stacked onto the first chip and the second chip being connected electrically to the circuitry of the first surface with gold lines; at least a third chip positioned at the lower section of the opening of the second surface and having a size smaller than the first chip, and a plurality of protruded blocks being used to electrically bond with the center position of the first chip, and adhesive being used to fill the first chip and the third chip, and the region between the first chip with the substrate.

### BACKGROUND OF THE INVENTION

(a) Field of the Invention

The present invention relates to an open-typed multi-chip stack packaging, and in particular, a packaging with at least three layers of stacked chips employing flip-chip packaging and wire bonding technology. The packaging effectively improves the number of I/O and functions thereof.

(b) Description of the Prior Art

Referring to FIG. 1A, there is shown a conventional multi chip packaging essentially comprising a substrate 1′ having a surface adhered with a first chip 2′ by means of wire-bonding technology. A gold line 21′ connected from the first chip 2′ to the substrate 1′ and are electrically bonded. A second chip 3′ having a smaller size as compared to the first chip 2′ is adhered to the top face of the first chip 2′. Similarly, gold line 31′ is bonded to the first face 11′ of the substrate 1′. The first surface 11′ of the substrate 1′ utilizes multi-layered circuit track to transmit signal to the solder ball 5′ of the second layer 12′. Finally, a packaging material is used to cover the chip and the gold lines 21′, 31′ to form a packaging body 4′.

FIG. 1B is another conventional art, wherein the center of the substrate 1′ is provided with an opening 13′ and a protruded block 21′ of the first chip 2′ is bonded to the surrounding region of the opening of the first surface 11′. The protruded block 31′ of the second chip 3′ is soldered at the center region at the lower section of the first chip 2′, and an adhesive is used for sealing the structure to form a packaging body A′.

The above conventional structures do not provide high I/O density and do not comply with the requirement for low production cost.

### SUMMARY OF THE INVETION

Accordingly, it is an object of the present invention to provide an open-typed multi-chip stack packaging, which mitigates the drawbacks of the conventional packaging.

Yet another object of the present invention is to provide an open-typed multi-chip stack packaging, wherein at least three layers of stacked chips can be obtained and flip-chip packaging and wire bonding technologies are employed in the packaging. The packaging of the present invention also effectively improves the number of I/O and functions thereof.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIGS. 1A and 1B schematically shows a conventional multi-chip stack packaging.

FIG. 2 is a schematic sectional view of an open-typed multi-chip stack packaging of the present invention.

FIG. 3 is a schematic sectional view of another preferred embodiment of the present invention.

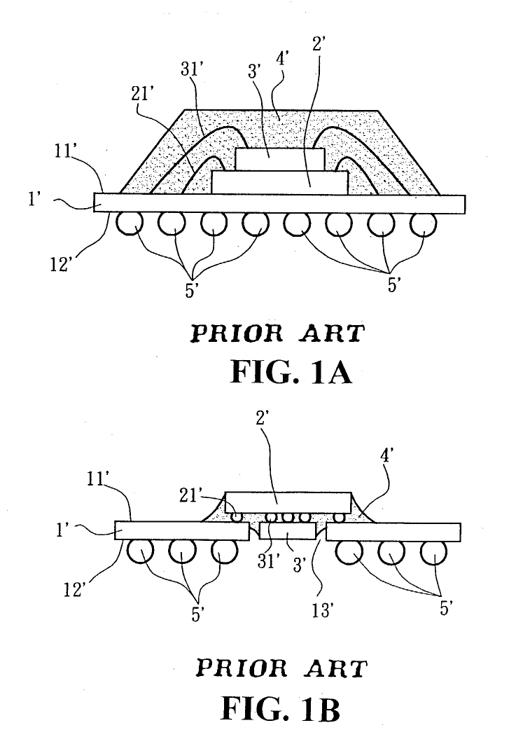

### DETAILED DESCRIPTION OF THE PRESENT INVENTION

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

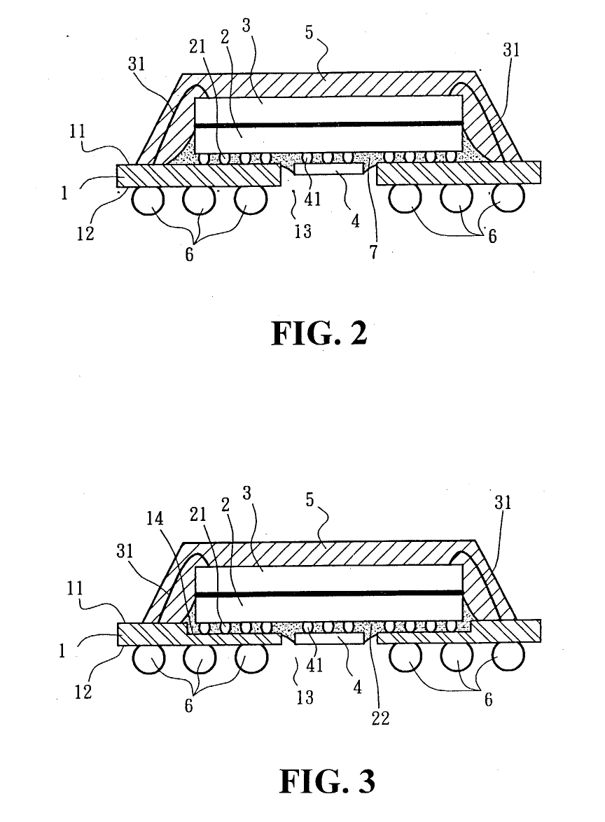

Referring to FIG. 2, there is shown an open-typed multi-chip stack-packaging comprising a substrate 1 having a first surface 11 and a second surface 12, at least a through opening 13 formed on the substrate 1, and including at least two layers of circuitry to electrically transmit signals such that the circuit signals on the first surface 11 can be transmitted to the second surface 12; at least a first chip 2 positioned on the upper section of the opening 13 of the first surface 11 and a plurality of protruded blocks 21 being soldered onto the circuitry on the first surface 11 of the substrate 1 at the external region of the substrate 1 for electrically connection; at least a second chip 3 stacked onto the first chip 2 and the second chip 3 being connected electrically to the circuitry of the first surface 11 with gold lines 31; at least a third chip 3 positioned at the lower section of the opening 13 of the second surface 12 and having a size smaller than that of the first chip 2, and a plurality of protruded blocks 41 being used to electrically bond at the center position of the first chip 2, and an adhesive 7 being used to fill on the first chip 2 and the third chip 3, and the region between the first chip 2 and the substrate 1; and a packaging body 5 covering the second chip 3 and the external surrounding of the gold lines 31 bonded with the substrate 1 from the upper section of the first surface 11 of the substrate 1.

Referring to FIG. 3, there is shown of another preferred embodiment of multi-chip stack packaging in accordance with the present invention. As shown in the figure, the external surrounding of the position of the opening 13 of the first surface 11 of the substrate 1 is provided with a recess 14 larger than the opening 13 and the bonding of the protruded block 21 of the first chip 2 is on the surface of the recess 14.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. An open-typed multi-chip stack-packaging comprising:
a substrate having a first surface and a second surface, at least a through opening formed on the substrate, and including at least two layers of circuitry to electrically transmit signals;
at least a first chip positioned on the upper section of the opening of the first surface and a plurality of protruded blocks being soldered onto the circuitry on the first surface of the substrate at the external region of the substrate for electrically connection;
at least a second chip stacked onto the first chip and the second chip being connected electrically to the circuitry of the first surface with gold lines;
at least a third chip positioned at the lower section of the opening of the second surface and having a size smaller than the first chip, and
a plurality of protruded blocks being used to electrically bond with the center position of the first chip, and adhesive being used to fill the first chip and the third chip, and the region between the first chip with the substrate; and
a packaging body covering the second chip and the external surrounding of the gold lines bonded with the substrate from the upper section of the first surface of the substrate.

2. The packaging of claim 1, wherein the external surrounding of the position of the opening of the first surface is provided with a recess larger than the opening and the bonding of the first chip with the substrate is at the surface on the recess.
